(19) United States
(12) Patent Application Publication
(10) Pub. No.: US 2009/0226841 A1
(43) Pub. Date: Sep. 10, 2009

(54) PHOTOSENSITIVE PLANOGRAPHIC PRINTING PLATE AND FABRICATION PROCESS THEREOF

(75) Inventors: Kiyoshi Kamitani, Haibara-gun (JP); Yasuhiko Naruoka, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Minato-ku, Tokyo (JP)

(21) Appl. No.: 11/817,777

(22) PCT Filed: Feb. 28, 2006
(86) PCT No.: PCT/JP2006/304222

§ 371 Date: Sep. 4, 2007

(30) Foreign Application Priority Data
Mar. 3, 2005 (JP) 2005-059719

(51) Int. Cl. G03F 7/004; G03F 7/20

(52) U.S. Cl. 430/270.1; 430/302

(57) ABSTRACT

A photosensitive planographic printing plate which can avoid quality defects such as residue films and the like and improve yield, and a fabrication process thereof. A coating layer of a region corresponding to an edge portion of a PS plate is preparatorily cleared by coating removal. Hence, pressure fogging which is formed by pressure at a time of cutting of a web will not occur.

### BACKGROUND OF THE INVENTION

1. Technical Field

The present invention relates to a photosensitive planographic printing plate and a fabrication process thereof and more specifically relates to a photosensitive planographic printing plate which is particularly excellent in a multi-layer format, in which a plurality of coating layers are formed thereon, and to a fabrication process thereof

2. Description of the Related Art

A photosensitive planographic printing plate (hereafter referred to where appropriate as a PS plate) is commonly fabricated by: subjecting a support body, such as an aluminium plate in the form of a sheet or a roll or the like, to one or a suitable combination of surface processes, such as, for example, sandblasting, anodization, silicate treatment, other chemical processes and so forth; then applying a photosensitive liquid and performing a drying process; and thereafter cutting the PS plate to a desired size. This PS plate is subjected to platemaking processes, such as exposure, development processing, gumming and the like, is set in a printer and coated with ink, and hence prints text, images and the like onto paper.

Printing using such PS plates includes general commercial printing and newspaper printing. In general commercial printing, it is common for a sheet-fed printer to be used to print onto sheets of paper, and for the printing paper to be smaller than the PS plate.

In newspaper printing, it is common for an offset printer to be used to print onto a web of paper, and for a breadth of the PS plate to be narrower than a width of the web of printing paper. As a result, in newspaper printing using an offset roller, ink that adheres to a cut edge (an “ledge portion”) of the PS plate is printed onto and soils the printing paper (“edge soiling”), and commercial value of the printed product is adversely affected.

Heretofore, at conventional printing plates and direct printing plates for newspapers, in order to prevent edge soiling during printing, techniques of forming roll-offs, cutaways, angled faces and the like at edge regions of plate materials, and techniques of applying desensitization processing, hydrophilization processing and the like to side faces of edge portions have been utilized.

For example, Japanese Patent Application Laid-Open (JP-A) No. 57-46754 describes a process for preventing edge soiling, in which cutaway portions are formed along two opposing edges or four edges of a support formed of aluminium, and Japanese Patent Application Publication (JP-B) No. 62-61946 describes a process for preventing edge soiling by performing desensitization processing at cut faces.

Further, as described in JP-B No. 4-78404, burrs which are formed at a time of cutting are one cause of soiling. Accordingly, in JP-B No. 4-78404 there is a process of intersectingly cutting in two directions, upward and downward, so as to prevent the occurrence of burrs at a printing face side. In Japanese Patent No. 2,614,976, a process for preventing edge soiling is proposed in which a cutting end portion is curved away from a printing face side for slitting.

In the aforementioned process of forming cutaway portions along edge portions of a support, it is necessary to extract the PS plates one at a time to form the cutaway portions, which is unsuitable for mass processing. Furthermore, when defects which will lead to adherence of ink occur, such as burrs, scratches and the like, ink gets caught at regions at which such defect portions are formed, and ultimately printing paper surfaces are stained with this ink. Further, with a process of applying a desensitization fluid to cut faces, the PS plates may adhere together and handling may be adversely affected, which may lead to development problems.

Further yet, if only the occurrence of burrs at a printing face side during cutting is prevented, soiling can occur due to printing conditions. Further again, although a shape in which cutting edge portions are curved downward (to a side opposite from the printing surface) tends to ameliorate soiling, there is a problem with the PS plate getting stuck during conveyance by a platemaking machine which performs exposure and development, or the like, and conveyance failures may result.

As a remedial measure to substitute for the above measures, the publications of Japanese Patent Nos. 2,910,950, 3,068,410 and 3,036,433 and JP-A Nos. 9-323486, 10-35130 and 10-100566 disclose that it is effective, when shearing PS plates with a slitter, a cutter or the like, to form cutaways with “sheared roll-offs” at edge portions of a surface-processing layer at the same time as the shearing.

In order to form cutaways which are effective for preventing soiling of printing paper surfaces, by a shearing process which employs a slitter, a cutter or the like, it is necessary to precisely control spacing, bite amounts and the like of shearing blades. Therefore, consequent to variations in conditions of shearing blade abrasion and the like, problems may arise with burrs, cracks in an oxidation layer and the like.

When large burrs form at, for example, a rear face (a face at the opposite side from the face at which a surface processing layer is formed), problems arise in that the PS plate meanders when the PS plate is being conveyed in an exposure device, the burrs drop off and become waste matter, and so forth.

Moreover, at a time of shearing, large cracks are formed at a front face (the face at which the surface processing layer is formed), which may have an effect on the printed product. Further, when performing multiple slitting, there is a problem in that there are losses between slits.

With modern direct printing plates, depending on formulas and layer structures, quality defects such as residue films and the like arise with conventional edge-machining technology. This leads to a reduction in productivity in comparison with conventional-type printing plates which do not utilize techniques for forming roll-offs and, depending on types, reductions in edge quality may be unavoidable.

JP-A No. 2003-94233, for example, has proposed reducing a spacing of cutting blades in cleaving of photopolymer-based photosensitive printing plates as a method for preventing the formation of cracks. With this method, although it is possible to prevent cracks, formation of roll-off shapes for ameliorating edge soiling is difficult. Further, the publications of JP-A Nos. 11-48629, 2001-130153, 2001-79719, 2001-219663 and 2001-322024 have described processes for forming particular roll-off shapes at edge portions, with press devices, pressure rollers and the like, as processes for regulating edge shapes by methods other than cutting. Further still, JP-A No. 2001-1656 has described a process of forming a recess portion with a pressure roller and cutting that portion.

With these processes, it is possible to form effective edge shapes. However, with direct printing plates, which have weak surfaces, there is significant concern that, depending on formulas and layer structures, quality defects such as residue films and the like may be induced.

In cutting of, for example, a photopolymer-based photosensitive printing plate, a photosensitive layer is susceptible to being fogged by slight pressure and forming a residue film. Thus, shape control by a press device, a pressure roller or the like is inappropriate. Accordingly, pressure fogging can be alleviated with methods which are described in the publications of JP-A Nos. 2001-205949 and 2001-205950 as cutting methods which avoid pressure fogging. However, the formation of roll-off shapes to alleviate edge soiling is more difficult, and there is a problem in that there are losses between slits when multiple slitting is performed.

In order to solve such problems, for example, the following have been considered: forming a cutaway in a step before forming a surface processing layer at a support body or the like; performing machining in a fabrication process before coating; preparatorily forming a roll-off shape at a region which is sliced or cross-cut beforehand, leaving that region uncoated in forming a coating layer, and slicing or cross-cutting the uncoated region; and the like.

Further, there are cases in which, from a long belt-form web, pluralities of PS plates in a width direction are formed by multiple slitting. In such a case, it is necessary to form recess portions beforehand at regions of the multiple slits. In order to realize these recess portions, high-accuracy web/sheet-handling technology and accurate coating technology are required. Thus, technological complexity is high and productivity is greatly reduced.

Further, that photosensitive planographic printing plates have numerous sizes is a significant feature of the products. In order to reduce storage space and shorten shipping lead times, estimating production is unavoidable for a mass production process.

Generally, a system in which sheaves of sheets which have been cut to a master size are stored, size changes are performed with a guillotine, a sheet-slitter or the like and then the sheets are shipped, and a system in which half-finished products which have been coated are stored in rolls, cross-cut in accordance with orders and then shipped are known. In such mass production processes, it is difficult to specify cross-cutting portions prior to the earlier coating, so it is difficult to preparatorily apply the coating in accordance with the cross-cutting portions.

In this context, fabrication processing technologies which assure edge qualities similar to conventional-type printing plates for CTP plates, and technologies which prevent edge soiling without causing cut-off losses for newspaper printing, in which roll-off shapes are required at sheet end portions, have become necessary.

### SUMMARY OF THE INVENTION

In consideration of the circumstances described above, an object of the present invention is to provide a photosensitive planographic printing plate which can avoid quality defects such as residue films and the like and can improve yield (i.e., production efficiency in relation to coating width), and a fabrication process thereof.

A first aspect of the present invention is a photosensitive planographic printing plate at which a coating layer is formed on a support body which coating layer is to be exposed and developed, wherein a coating removal portion is formed at at least one edge of the photosensitive planographic printing plate, at which coating removal portion the coating layer has been cleared by coating removal.

Because an image will not be formed at an edge region (end portion) of the photosensitive planographic printing plate, there will be no adverse effect in practice if there is no photosensitive layer (coating layer) thereat. Accordingly, in this first aspect of the present invention, the coating removal portion, from which the coating layer has been cleared by coating removal, is provided at the at least one edge of the photosensitive planographic printing plate.

The coating layer is cleared from the edge region of the photosensitive planographic printing plate, that is, a slicing or cross-cutting portion of the photosensitive planographic printing plate. Thus, pressure fogging which is caused by pressure forces during slicing or cross-cutting will not arise.

Furthermore, fogging which is caused by a surface of the support body being exposed, due to the occurrence of cracks at a slicing or cross-cutting portion of the photosensitive planographic printing plate, and a polymer reaction being caused by provision of electrons to the surface (i.e., “crack fogging”) will not arise.

Accordingly, cutting waste at a time of cutting can be reduced, and yield (production efficiency in relation to coating width) can be improved.

A second aspect of the present invention is a process for fabrication of a photosensitive planographic printing plate which is formed as a sheet by slicing or cross-cutting, the process including: forming a coating layer on a continuously running web, the coating layer being structured with at least one functional coating film; at an edge portion of at least one edge of the sheet-form photosensitive planographic printing plate, clearing the whole or a surface portion of the coating layer by coating removal; and after the clearing by coating removal, slicing or cross-cutting a coating removal portion, which has been cleared by the coating removal, at the edge portion.

In the process of the second aspect of the present invention, the coating layer that has been coated at the region of slicing or cross-cutting is cleared by coating removal and then, after the coating removal portion is sliced or cross-cut, an edge portion of the photosensitive planographic printing plate coincides with the coating removal portion. Because the coating layer has been cleared by coating removal before the slicing or cross-cutting, pressure fogging will not occur at the edge portion of the photosensitive planographic printing plate.

A third aspect of the present invention is a process for fabrication of a photosensitive planographic printing plate which is formed as a sheet by slicing or cross-cutting, the process comprising forming a coating layer on a continuously running web, the coating layer being structured with at least one functional coating film; slicing or cross-cutting an edge portion of at least one edge of the sheet-form photosensitive planographic printing plate; and after the slicing or cross-cutting, clearing the whole or a surface portion of the coating layer at the edge portion by coating removal.

In this process, after the slicing or cross-cutting, the coating layer at the whole or a surface portion of the coating layer is cleared by coating removal. Thus, fogging which would be caused by the occurrence of cracks at the slicing or cross-cutting region of the photosensitive planographic printing plate will not occur.

### BRIEF DESCRIPTION OF THE DRAWINGS

FIG. 1 is a schematic view showing a production line of planographic printing plates relating to an embodiment of the present invention.

FIG. 2 is a perspective view showing a cleaving section which cleaves planographic printing plates relating to the embodiment of the present invention.

FIG. 3 is a front view showing a rolling section which rolls the planographic printing plates relating to the embodiment of the present invention.

FIG. 4 is a front view showing the cleaving section which cleaves the planographic printing plates relating to the embodiment of the present invention.

FIG. 5A is a front view showing a positional relationship of an upper blade and lower blade of the cleaving section which cleaves the planographic printing plates relating to the embodiment of the present invention.

FIG. 5B is a sectional view showing a cleaved surface of FIG. 5A.

FIG. 5C is a front view showing a positional relationship of the upper blade and lower blade of the cleaving section which cleaves the planographic printing plate relating to the embodiment of the present invention.

FIG. 5D is a sectional view showing a cleaved surface of FIG. 5C.

FIG. 6A is a schematic view showing a conventional format of a planographic printing plate production line.

FIGS. 6B and 6C are schematic views showing planographic printing plate production lines relating to the embodiment of the present invention.

FIGS. 7A to 7C are sectional views showing processes of production of planographic printing plates corresponding to FIGS. 6A to 6C.

FIG. 8A is a plan view showing an ordinary planographic printing plate.

FIG. 8B is a plan view of a planographic printing plate relating to the embodiment of the present invention.

FIG. 8C is a sectional view of FIG. 8B.

FIGS. 9A and 9B are plan views showing states in which planographic printing plates have been subjected to coating removal.

FIGS. 10A and 10B are explanatory views showing conditions of a coating layer of a planographic printing plate.

FIG. 11A is a plan view showing a newspaper printing system.

FIG. 11B is a plan view showing a commercial printing system.

FIG. 12 is a schematic view showing a slitless-type planographic printing plate production process.

FIG. 13 is a schematic view showing a two-end slitting-type planographic printing plate production process.

FIG. 14 is a schematic view showing a multiple slitting-type planographic printing plate production process.

FIG. 15 is a schematic view showing a multiple/two-end slitting-type planographic printing plate production process.

FIG. 16 is a schematic view showing a multiple cut-out slitting-type planographic printing plate production process.

### DETAILED DESCRIPTION OF THE INVENTION

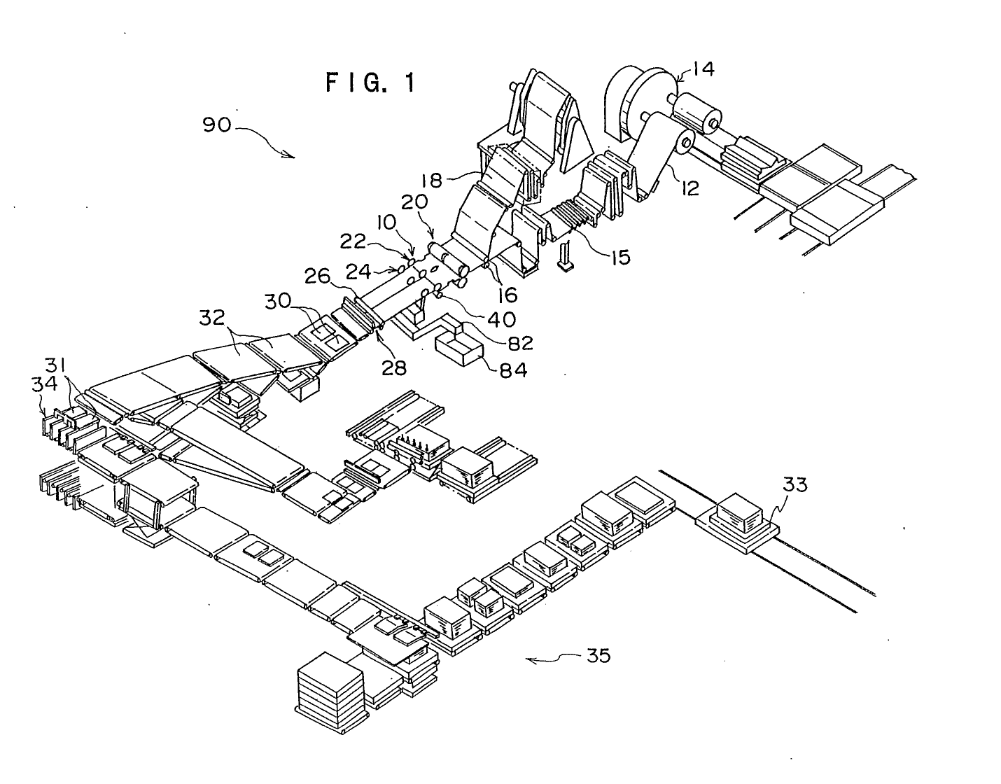

FIG. 1 shows a production line 90 of usual photosensitive planographic printing plates (hereafter referred to as PS plates). A feeding machine 14, which sequentially unwinds a web 12 which has been previously wound into a roll, is disposed at an upstream side of this production line 90 (the upper-right side of FIG. 1). The long strip-form web 12 which is unwound by the feeding machine 14 is treated for curling by a leveller 15. The web 12 reaches feeding rollers 16, and interleaf paper 18 is applied to the web 12 and adhered by static electricity. Then, the web 12 reaches a notcher 20.

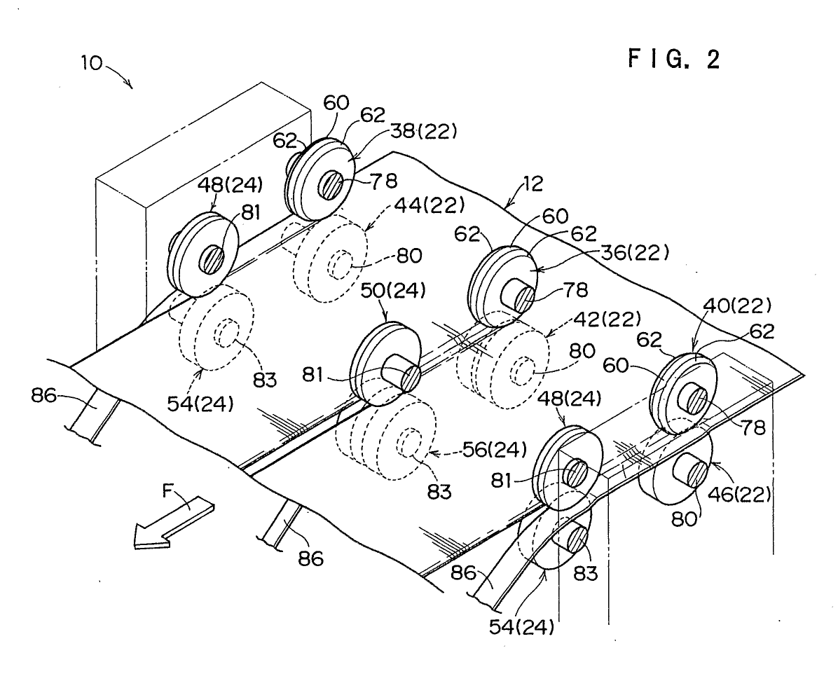

The notcher 20 forms punch-out portions in the web 12. Upper blades 48 and 50 of a cleaving roller 24 which structures a cleaving section 10 (see FIG. 2 for all of these) are capable of moving in a width direction of the web 12 to positions of the punch-outs. Thus, a cutting width of the web 12 can be altered while the web 12 and the interleaf paper 18 are both together being continuously cleaved or longitudinally cut. Hereafter, where a width direction is referred to without elaboration, this means a lateral direction of the web 12 that is being conveyed (i. e., is running), and when an inner side or outer side is referred to, this means an inner side or outer side, respectively, of the web 12 in the width direction.

Now, planographic printing plate production processes include the following two processes: a process of continuously slicing/laterally cutting (or continuously cross-cutting/laterally and longitudinally cutting) the web-form printing plate, at which surface processing has been performed and a coating layer has been formed, and finishing to sheet-form finished products; and a process of continuously slicing the web-form printing plate and finishing to a sheaf of sheet-form semi-manufactured products, re-processing the sheet-form semi-manufactured products (sheaf-cutting or sheet-cutting with a guillotine or a slitter or the like), and finishing to sheet-form finished products. The former process will be described for a present embodiment.

Further, as processes for producing a web or sheets, there are: a process of continuously slitting the web or sheets with a rotating blade; a process of continuously cutting the web with a rotary cutter, a flying shear or the like; and a process of cleaving sheets or sheaves of sheets with a guillotine. “Cleaving” means continuous slitting, and “slicing” means continuous cutting.

Cutting waste 86 which is generated from cleaving by the cleaving section 10 is transported to an unillustrated chopper and narrowly sliced, and is then recovered to a recovery container 84 by a recovery conveyor 82.

A feeding length of the web 12 that has been cleaved to a predetermined cleaving width is detected by a measurement apparatus 26, and the web 12 is sliced by a running cutter 28 with a specified timing. Thus, PS plates (product sheets) 30 with specified sizes are fabricated.

Next, the PS plates 30 are fed to a stacking section 34 by a conveyor 32, and predetermined numbers of the PS plates 30 are piled up to constitute stacked sheaves 31. At the stacking section 34, protective sheets (commonly referred to as cover sheets), which are formed of thick paper or the like, may be disposed at top and bottom and/or sides of the stacked sheaves 31.

Then, the stacked sheaves 31 are passed through a conveyance section 35 and piled on pallets 33. Thereafter, the stacked sheaves 31 are fed to a storage place, such as a rack warehouse or the like, or to a packing process, to be packed with packing materials (tape, an inner wrapper, an outer wrapper or the like). Alternatively, the stacked sheaves 31 may be piled on skids for an automatic platemaking machine (flat skids, standing skids or the like).

Here, if the stacked sheaves 31 are to be piled on such skids and packed, a stacking apparatus for stacking the stacked sheaves 31 on the skids may be provided at the production line 90, and the stacked sheaves 31 directly stacked on skids within the production line 90.

Further, while the interleaf paper 18 is applied to the web 12 herein, this is merely an example of an embodiment; the interleaf paper 18 is not necessarily required. Similarly, the present embodiment is not limiting with regard to packing materials.

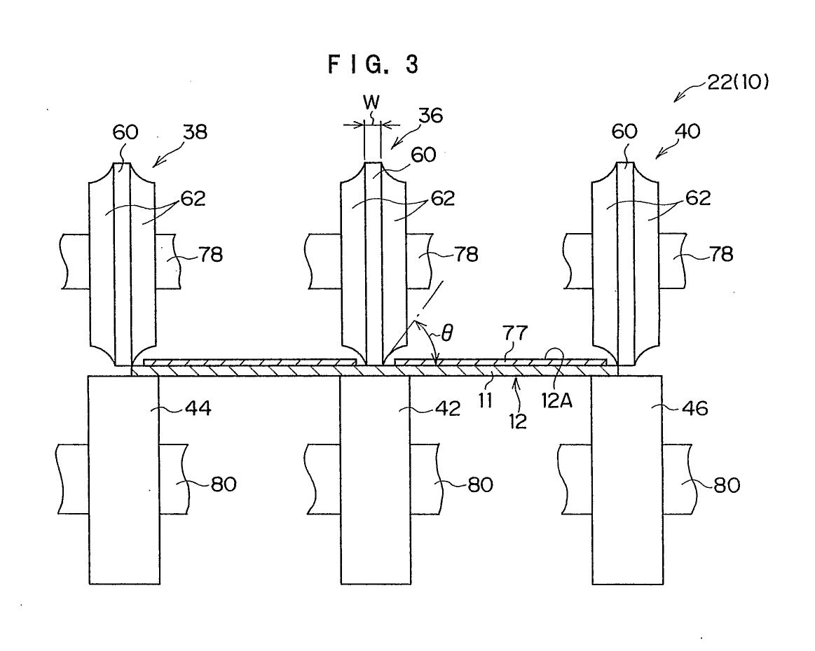

Anyway, at the web 12, an under-coating layer, a photosensitive layer, an over-coating layer and the like have been coated beforehand onto a support 11 made of aluminium (see FIG. 3) to serve as “functional layers” (below referred to as a coating layer 77; see FIG. 3). The face at which this coating layer 77 is formed will be an image formation face of the PS plate 30.

The functional layers differ depending on the type of the printing plate. In a case of a conventional printing plate, an under-coating layer, a photosensitive layer and a matt layer are applied. In a case of positive thermal CTP, an under-coating layer, a photosensitive layer and a photosensitive overcoat layer are applied. In a case of negative thermal CTP, an under-coating layer, a photosensitive layer and an oxygen-blocking overcoat layer are applied. In a case of photopolymer CTP, an under-coating layer, a photosensitive layer and an oxygen-blocking overcoat layer are applied. In a case of processless CTP, an under-coating layer, a photosensitive layer and an oxygen-blocking or ink-repelling overcoat layer are applied.

Hence, the web 12 is processed by the production line 90 and formed to a desired size, thus forming the PS plates 30 which can be used in printing.

For the aluminium plate which serves as the support 11 (the web 12), for example, a JIS1050 material, a JIS 1100 material, a JIS1070 material, an Al—Mg-based alloy, an Al—Mn-based alloy, an Al—Mn—Mg-based alloy, an Al—Zr-based alloy, an Al—Mg—Si-based alloy or the like can be employed. In an aluminium plate fabrication process at a maker thereof an aluminium ingot meeting the above-mentioned specifications is fabricated. This aluminium ingot is hot-rolled, then subjected to a heating process known as annealing in accordance with requirements, formed to a predetermined thickness by cold-rolling, and finished to a strip-form aluminium plate.

Specific structure of the web 12 is not particularly limited herein, but the web 12 will be capable of forming planographic printing plates which enable direct platemaking from digital data, by being formed as planographic printing plates for laser printing in, for example, heat-mode systems and photon systems.

At the web 12, the coating layer 77 is formed at one face of the support 11 made of aluminium, which is formed in a rectangular plate shape. Platemaking processes such as exposure, development processing, gumming and the like are applied to the coating layer 77, the web 12 is set in a printer and coated with ink, and hence prints text, images and the like onto paper.

By selection of various components in a photosensitive layer or a heat-sensitive layer, the web 12 can be formed into planographic printing plates corresponding to various platemaking processes. Examples of specific modes of the planographic printing plates of the present invention are shown by the following modes (1) to (11).

(1) A mode in which a photosensitive layer contains an infra-red absorbent, a compound which generates oxygen when heated, and a compound which is cross-linked by oxygen.

(2) A mode in which a photosensitive layer contains an infra-red absorbent and a compound which becomes alkali-soluble when heated.

(3) A mode in which a photosensitive layer includes two layers: a layer which contains a compound which generates radicals when illuminated with laser light, a binder which is soluble in an alkali, and a multifunctional monomer or prepolymer; and an oxygen-blocking layer.

(4) A mode in which a photosensitive layer includes two layers: a physical development center layer; and a silver halide emulsion layer.

(5) A mode in which a photosensitive layer includes three layers: a layer which contains a multifunctional monomer and a multifunctional binder; a layer which contains silver halide and a reducing agent; and an oxygen-blocking layer.

(6) A mode in which a photosensitive layer includes two layers: a layer which contains a novolac resin and napthoquinone diazide; and a layer which contains silver halide.

(7) A mode in which a photosensitive layer includes an organic photoconductive body.

(8) A mode in which a photosensitive layer includes two or three layers: a laser light-absorbing layer, which is removed by illumination with laser light; a lipophilic layer; and/or a hydrophilic layer.

(9) A mode in which a photosensitive layer contains a compound which absorbs energy and produces acid, a high polymer compound including functional groups in side chains, which produces sulfonic acid or carboxylic acid when acid is applied, and a compound which provides energy to the acid-forming agent by absorbing visible light.

(10) A mode in which a photosensitive layer contains a quinone diazide compound and a novolac resin.

(11) A mode in which a photosensitive layer contains a compound which is decomposed by light or ultraviolet rays and forms a cross-linking structure with itself or with other molecules in the layer, and a binder which is soluble in alkali.

In particular, planographic printing plates to which coating layers of high-sensitivity photosensitive types to be exposed with laser light are applied, planographic printing plates of heat-sensitive types and the like have been employed in recent years (for example, the above-described modes (1) to (3) and suchlike).

Meanwhile, wavelengths of laser light are not particularly limited herein. Examples can include the following.

(a) Lasers in the wavelength region 350 to 450 nm (a specific example being a laser diode with a wavelength of 405±5 nm).

(b) Lasers in the wavelength region 480 to 540 nm (specific examples being an argon laser with a wavelength of 488 nm, an (FD) YAG laser with a wavelength of 532 nm, a solid laser with a wavelength of 532 nm and a (green) He—Ne laser with a wavelength of 532 nm).

(c) Lasers in the wavelength region 630 to 680 nm (specific examples being He—Ne lasers with wavelengths of 630 to 670 nm and infrared semiconductor lasers with wavelengths of 630 to 670 nm).

(d) Lasers in the wavelength region 800 to 830 nm (a specific example being an infrared (semiconductor) laser with a wavelength of 830 nm).

(e) Lasers in the wavelength region 1064 to 1080 nm (a specific example being a YAG laser with a wavelength of 1064 nm).

Of these, it is possible to employ, for example, laser light in either of the wavelength regions of (b) and (c) with planographic plates including either of photosensitive layers of the above-described modes (3) and (4) and heat-sensitive layers. Further, it is possible to employ laser light in either of the wavelength regions of (d) and (e) with planographic plates including either of photosensitive layers of the above-described modes (1) and (2) and heat-sensitive layers. Obviously, correspondences between wavelength regions of laser light and photosensitive layers or heat-sensitive layers are not limited thus.

Shape and the like of the web 12 are not particularly limited. For example, the web 12 could be an aluminium plate with a thickness of 0.1 to 0.5 mm and a width of 650 to 3150 mm, with a photosensitive layer or a heat-sensitive layer applied to one or both sides thereof, or the like.

Interleaf paper that is employed may be an interleaf paper that is ordinarily employed with planographic printing plates. A representative example is illustrated below. Specific structure of the interleaf paper 18 is not limited as long as the interleaf paper 18 is capable of reliably protecting a coating layer of the web 12. For example, paper which employs 100% wood pulp, paper which employs synthetic pulp rather than employing 100% wood pulp, such papers with a low-density polyethylene layer applied to the surface thereof, and the like can be employed. In particular, with a paper which does not employ synthetic pulp, material costs are lower, so the interleaf paper 18 can be fabricated at lower cost. A more specific example is interleaf paper with a basis weight of 20 to 55 g/m² produced from bleached kraft pulp, with a density of 0.7 to 0.85 g/cm³, a water content of 4 to 6%, a Beck smoothness of 10 to 800 seconds, a pH of 4 to 6, and an air permittivity of 15 to 300 seconds. Obviously, this example is not limiting.

Anyway, as shown in FIG. 2, the cleaving section 10 which cleaves the web 12 is structured with a rolling section 22 and the cleaving section 10. The rolling section 22 is provided at the upstream side in the direction of conveyance of the web 12 (which is the direction of arrow F), and the cleaving section 10 is provided at the downstream side of the rolling section 22.

As is shown in FIGS. 2 and 3, the rolling section 22 is structured with upper rollers 36, 38 and 40 at a front face 12A side of the web 12, which are disposed at predetermined positions in the width direction of the web 12, and lower rollers 42, 44 and 46 at a lower side of the web 12, which are disposed to correspond with the upper rollers 36, 38 and 40.

Here, numbers of the upper rollers and lower rollers are determined by how many of the PS plates 30 are to be obtained in the width direction of the web 12. For the present embodiment, as an example, a case in which two PS plates 30 are to be obtained in the width direction is illustrated, with the upper roller 36 and the lower roller 42 being substantially central in the width direction of the web 12, and the upper rollers 38 and 40 and lower rollers 44 and 46 being at width direction end portions.

The upper rollers 36, 38 and 40 are respectively axially supported at a shaft 78, and can be rotated at a speed the same as that of the web 12. The upper rollers 36, 38 and 40 are formed in substantial disc shapes overall, with pressing portions 60 formed substantially centrally in the axial direction. Each pressing portion 60 has a certain radius and width (i.e., length in the axial direction) W. An angle that an outer peripheral face of the pressing portion 60 forms with the front face 12A of the web 12 can be suitably selected, but may be set to be substantially parallel with the front face 12A.

From both axial direction sides of the pressing portion 60, inclined portions 62 are formed in truncated conical shapes, diameters of which reduce gradually towards distal ends thereof. An outer peripheral face of each inclined portion 62 is formed to a shape in which a portion thereof that is disposed furthest downward is inclined by a certain angle of inclination e with respect to the front face 12A of the web 12.

Meanwhile, the lower rollers 42, 44 and 46 are respectively axially supported at a shaft 80, and can be rotated at a speed the same as that of the web 12, in the opposite direction to the upper rollers 36, 38 and 40. The web 12 is conveyed over the lower rollers 42, 44 and 46 in a state in which the coating layer 77 faces upward. Thus, continuous inclined faces are formed in the front face 12A of the web 12 by the inclined portions 62 of the upper rollers 36, 38 and 40, and flat faces are formed by the pressing portions 60.

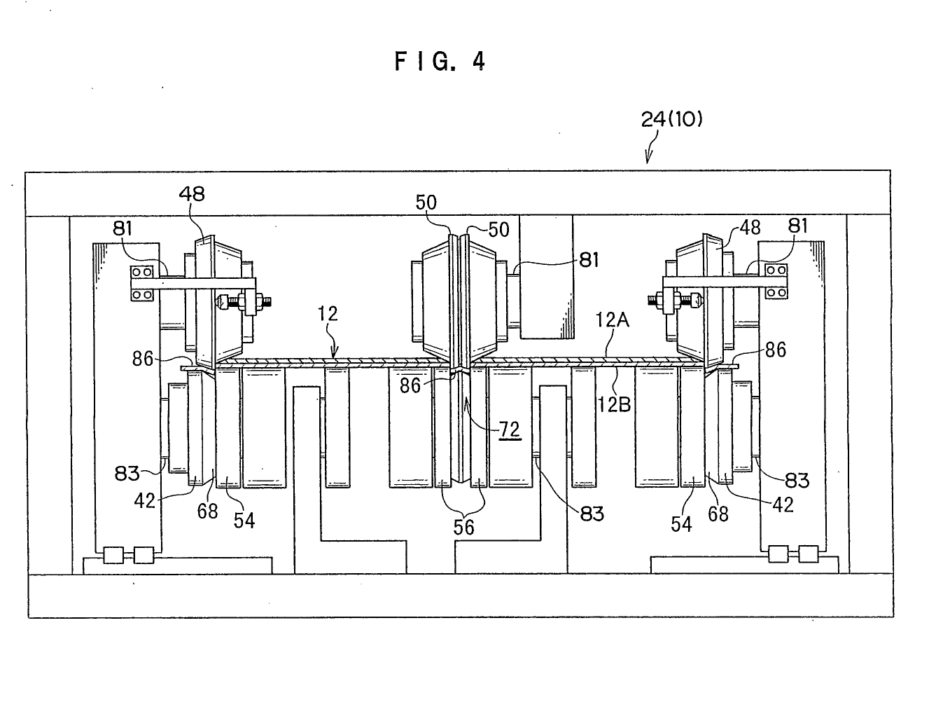

As shown in FIGS. 2 and 4, the cleaving section 10 is structured with upper blades 48 and 50 at the front face 12A side of the web 12, which are provided at width direction end portion (edge portion) vicinities and substantially centrally to the web 12 that is being conveyed, and lower blades 54 and 56, which are provided at a rear face 12B side of the web 12 to correspond with the upper blades 48 and 50.

The upper blades 48 and 50 are respectively axially supported at shafts 81, and can be rotated at a speed the same as that of the web 12. Meanwhile, the lower blades 54 and 56 are respectively axially supported at shafts 83, and can be rotated at a speed the same as that of the web 12, in the opposite direction to the upper blades 48 and 50.

Each of the width direction end portion vicinity upper blades 48 is formed in a substantial dish shape with a trapezoid form in front view. A large diameter side thereof is disposed so as to face toward the inner side in the width direction of the web 12. The upper blade 48 is formed with a predetermined position and diameter such that a portion thereof which is disposed furthest downward reaches further down than the rear face 12B of the web 12. Thus, the upper blades 48 serve as cleaving portions which cleave (trim) the web 12 by rotating.

The width direction central upper blades 50 are provided as a pair, each of which is formed in a substantial dish shape which is more truncated than the end portion vicinity upper blades 48. A large diameter side of the upper blade 50 is disposed so as to face toward the outer side in the width direction of the web 12. Similarly to the upper blades 48, the upper blade 50 is formed with a predetermined diameter such that a portion thereof which is disposed furthest downward reaches further down than the rear face 12B of the web 12. Thus, the upper blades 50 serve as cleaving portions which cleave the web 12 by rotating.

Each of the lower blades 54 provided at the width direction end portion vicinities is formed in a truncated tubular shape or cylindrical shape with a certain diameter. While supporting the web 12, the lower blade 54 nips the web 12 between the lower blade 54 and the upper blade 48 and cleaves the web 12. A lower roller 42A is provided at a width direction end portion relative to the lower blade 54. The lower roller 42A is formed overall with a smaller diameter than the lower blade 54, and includes a diameter reduction portion 68, at which the diameter gradually reduces toward the width direction inner side. When the web 12 is nipped and cleaved by the upper blade 48 and the lower blade 54, an end portion of the web 12 is supported by this lower roller 42 and is bent toward the diameter reduction portion 68. Thus, cleaving can be performed with ease.

In contrast, the lower blades 56 provided substantially centrally in the width direction are structured by rollers with truncated tubular shapes or cylindrical shapes, which have the same diameter as the end portion lower blades 54, being disposed in opposition with a predetermined gap 72 formed therebetween. Hence, the upper blades 50 enter into this gap 72, and the two upper blades 50, which form a certain gap therebetween, are disposed to be adjacent to the respective lower blades 56.

Thus, while supporting the web 12, the lower blades 56 nip the web 12 between the lower blades 56 and the upper blades 50 and cleave the web 12. Here, a portion that is cut out by the cleaving (i.e., cutting waste 86) passes into the gap 72. Thus, cleaving can be performed with ease. Of the web 12 which has been cleaved in this manner, portions between the upper blades 48 and the upper blades 50 (i.e., portions which are left uncut by the cleaving) will serve as the PS plates 30, which will be the final product (see FIG. 1).

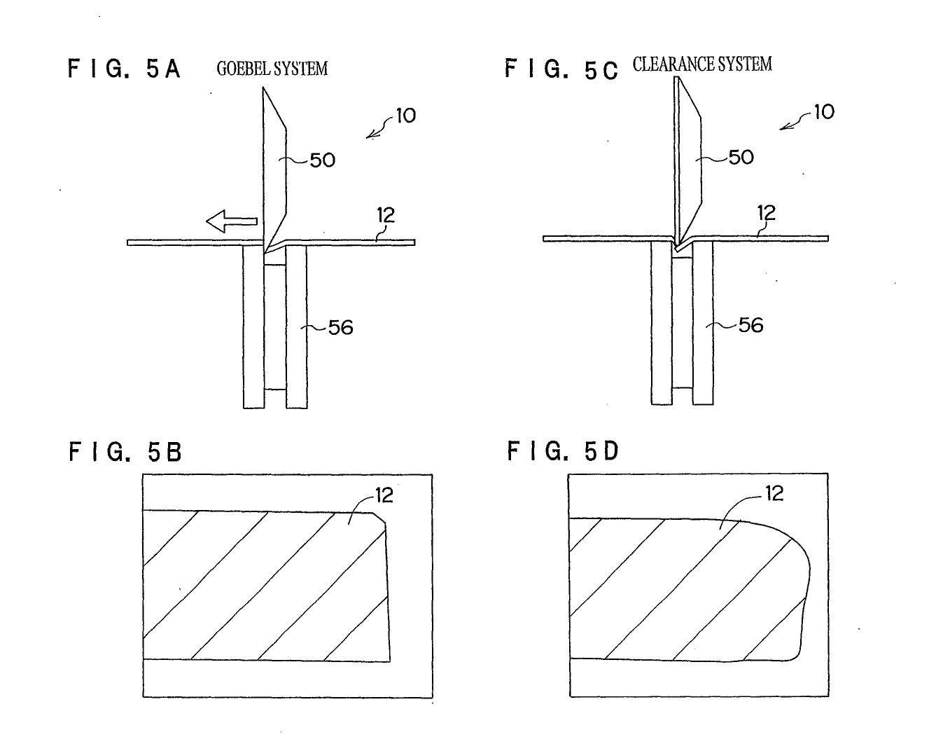

Incidentally, for a slitting system of the cleaving section 10, there may be a Goebel system (GE system) shown in FIG. 5A or a clearance system (PCS system) shown in FIG. 5C. FIGS. 5B and 5D show cross-sectional forms of edge portions of the web 12 resulting from the slitting systems of FIGS. 5A and 5C, respectively. Here, the difference between the Goebel system and the clearance system is the presence or absence of a clearance in a horizontal direction between the upper blade 50 and the lower blade 56.

That is, in a Goebel system, the upper blade 50 is pushed toward the lower blade 56 by an unillustrated spring, to set clearance between the upper blade 50 and the lower blade 56 to zero, while in a clearance system, in a state in which a position of the upper blade 50 is fixed, a clearance of 60 to 70 μm is formed between the upper blade 50 and the lower blade 56. Consequently, in cleavage by the Goebel system, the edge portion of the PS plate 30 is in an angular condition, while in cleavage by the clearance system, a roll-off is formed at the edge portion of the PS plate 30.

Next, key features of the PS plate production line relating to the embodiment of the present invention will be described.

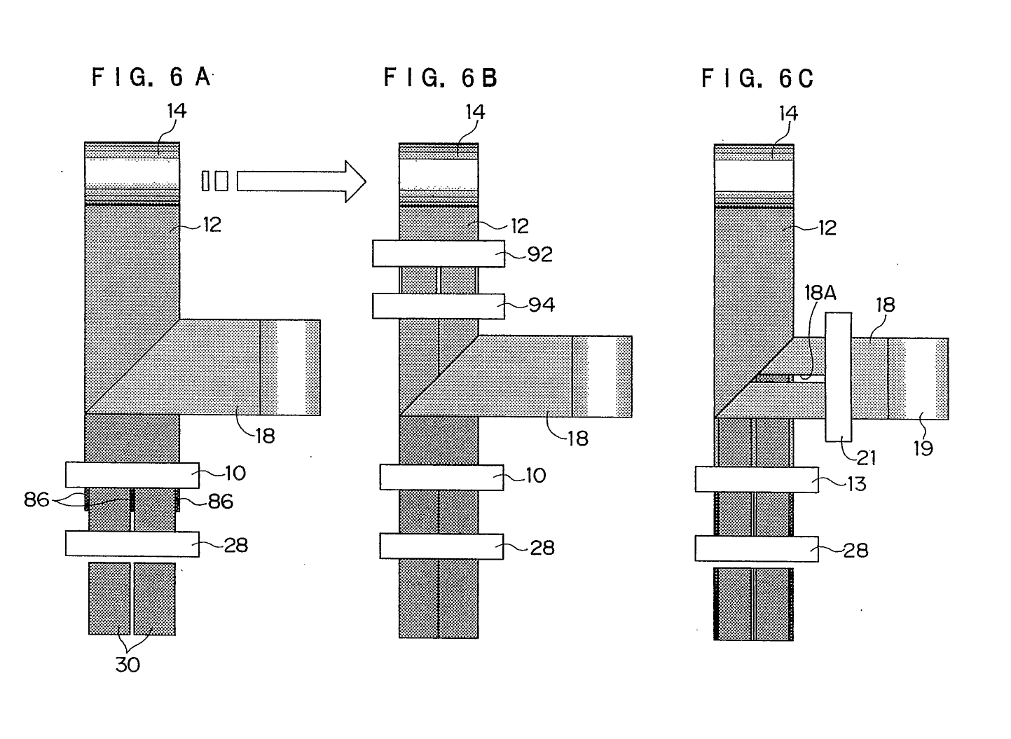

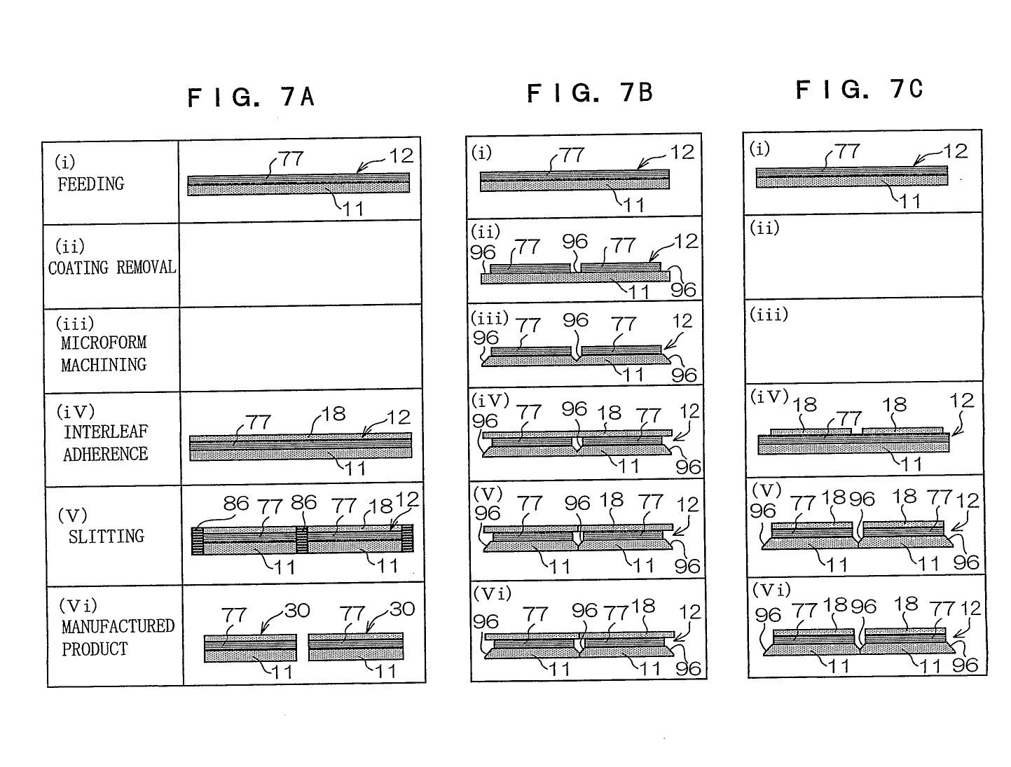

As shown in FIGS. 1 and 6A, after the web 12 has been unwound from the feeding machine 14, the interleaf paper 18 is applied to the web 12 (see (i) and (iv) in FIG. 7A). Then, the web 12 is cleaved by the cleaving section 10 (see (v) in FIG. 7A) and is sliced by the running cutter 28. Thus, the PS plates 30 with a specified size are produced (see (vi) in FIG. 7A). However, because an image will not be formed at an edge region of the PS plate 30, even if the coating layer 77 is absent from the edge region, no adverse effects will occur in practice.

Accordingly, in the present invention, as shown in FIG. 6B, a coating removal apparatus 92 is disposed at a downstream side of the feeding machine 14. The coating removal apparatus 92 is provided with, for example, a CO₂ laser (energy flux density=0.2 to 50 J/cm²·s, and wavelength λ=680 nm). The coating layer 77 at edge portions of the unwound web 12 (i.e., portions which correspond to edge portions of the PS plates 30) is cleared by coating removal by the CO₂ laser (see (i) and (ii) of FIG. 7B). The film that has been cleared by coating removal by the CO₂ laser in this manner is taken in by an unillustrated absorption apparatus.

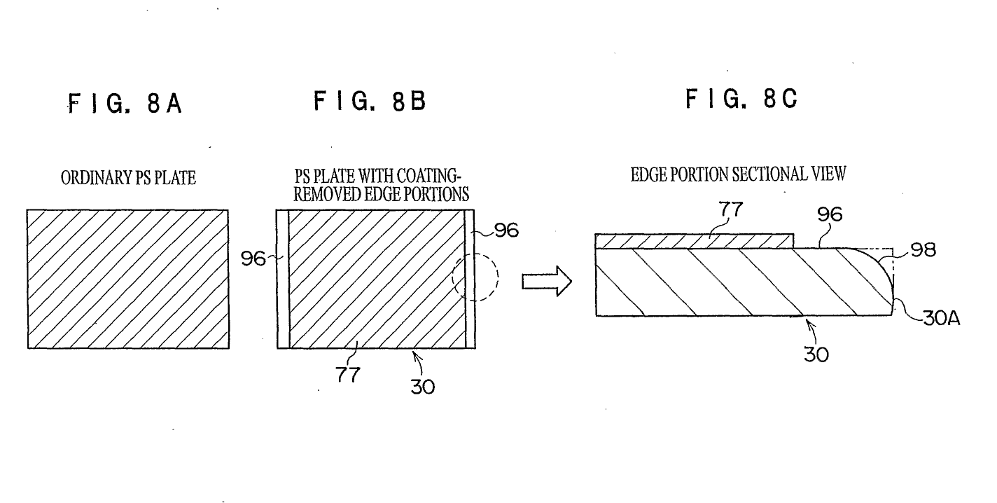

A microform machining apparatus 94, which performs, for example, the rolling processing shown in FIG. 3, is provided at a downstream side of the coating removal apparatus 92. At a coating removal portion 96, which has been cleared by coating removal by the coating removal apparatus 92, the microform machining apparatus 94 forms a roll-off portion 98 with the convex form shown in FIG. 8C. (FIG. 8A shows the usual PS plate 30, FIG. 8B shows a plan view of the PS plate 30 which has been cleared by coating removal, and FIG. 8C shows a sectional view of the PS plate 30 of FIG. 8B.) The roll-off portion 98 has a curved form here, but could be chamfered with a linear form.

The microform machining apparatus 94 may employ the clearance slit system described in JP-A No. 10-35130, the pressure roller system described in JP-A No. 2001-1656 and the press system described in JP-A No. 2001-130153, or the like. When such processes are applied to the coating removal portion 96, defects which cause cracking, such as alteration of the coating layer 77 or film oxidation, and the like can be prevented.

Then, after the roll-off portions 98 have been formed at the coating removal portions 96 by the microform machining apparatus 94 (see (iii) in FIG. 7B), the interleaf paper 18 is applied to the upper face of the web 12 (see (iv) in FIG. 7B). Next, the web 12 is conveyed to the cleaving section 10 and the coating removal portions 96 of the web 12 are cleaved with conditions such that the roll-off portions 98 are retained (see (v) in FIG. 7B), and the web 12 is sliced by the running cutter 28 to produce the PS plates 30.

Herein, a rolling process is employed at the microform machining apparatus 94, but it is also possible to employ a laser process, a grinding process, a shaving process or the like, However, in such cases, hydrophilization processing, oxidation processing and the like will be necessary after the roll-off portions 98 have been formed.

As described above, the coating layer 77 is preparatorily cleared by coating removal from the regions corresponding to the edge portions of the PS plate 30. Therefore, pressure fogging which would be caused by pressure forces during cleaving of the web 12 does not occur. If the PS plate 30 were employed to perform printing in a state in which pressure fogging had occurred, a residue film would be formed. However, because the pressure fogging does not occur, this residue film will not be formed.

Moreover, because the coating layer 77 is preparatorily cleared by coating removal from the regions corresponding to the edge portions of the PS plate 30, fogging which is caused by the surface of the aluminium being exposed, due to the formation of cracks at cleaving portions of the web 12, and a polymer reaction occurring because of provision of electrons to the surface, will not arise.

Further, grain 75 and an oxidation film 79 at the surface of the grain 75 are kept at the coating removal portion 96. In a state in which the PS plate 30 has been exposed and developed for platemaking, functions of preventing ink adherence at a non-image portion of the PS plate 30 and absorbing condensation are necessary. Therefore, after the coating layer 77 has been cleared by coating removal, the grain 75 and the oxidation film 79 are retained, such that hydrophilicity is maintained.

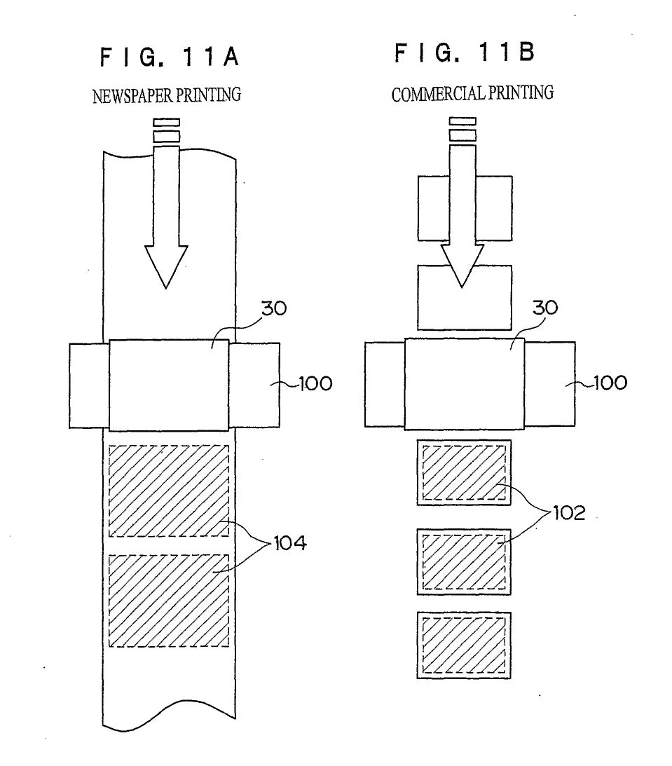

Further still, in order to prevent edge soiling of the PS plate 30, as well as providing hydrophilicity, it is important to form a state in which, in a printer, edge portions of the PS plate 30 and a blanket roller 100 of the printer (see FIGS. 11A and 11B) are unlikely to come into contact.

Accordingly, because the roll-off portion 98 is formed at a corner portion of the coating removal portion 96, pressure of the edge portion of the photosensitive planographic printing plate on the blanket roller 100 is reduced and ink is prevented from transferring from a side end face 30A of the PS plate 30 (see FIG. 8C) round onto the blanket roller 100. Thus, edge soiling of the PS plate 30 can be prevented.

Now, if the web 12 is to be continuously sliced or cross-cut, before the cleaving, coating removal processing is applied to regions of cleaving, then the roll-off portions 98 are formed (by shape control) at the coating removal portions 96 by the microform machining apparatus 94, and then the coating removal portions 96 are cleaved in conditions in which the roll-off portions 98 are retained, and the web 12 is sliced into sheets. At this time, it is possible to form particular roll-off shapes at which the coating layer 77 is not present at two edges which have been cleared by coating removal, shape-controlled and cleaved.

When the PS plate 30 is loaded in a printer, in a state in which the PS plate 30 is wound onto a plate roller (not shown), end portions (retained portions) of the PS plate 30 are retained by retention members of the plate roller. Therefore, the retained portions are not a concern in regard to problems of pressure fogging and the like. Consequently, it is not necessary for the retained portions of the web 12 (i.e., regions which are gripped by the retaining members) to be subjected to coating removal processing.

When the sheet-form PS plates 30 are being produced, it is also possible to supply the PS plates 30 one at a time and cleave the same after regions to be cleaved have been cleared by coating removal to narrow widths. By implementing this at all four sides, it is possible to manufacture the PS plates 30 with coating removal regions formed at all four edges.

Further, if a recess portion with a width of the order of 1 mm is formed by a pressure roller or the like at a region from which the coating layer 77 has been cleared by coating removal and then the middle of the recess portion is cleaved, because the recess portion has been formed beforehand, there is no need to form a roll-off shape at the same time as the cleaving. Therefore, in a case of multiple slitting, the cutting waste 86 is not generated.

Further yet, it is possible, by applying desensitization processing to the coating removal portion 96, to further ameliorate edge soiling of the PS plate 30. In the desensitization processing, a processing method and processing chemicals as described in, for example, JP-B No. 62-61946, Japanese Patent No. 3,442,875, JP-A No. 11-52579 or the like are applied to the coating removal portion 96.

Now, in the present mode, a distance between the coating removal apparatus 92 and the cleaving section 10 is long. Consequently, positional control of edge portions of the web 12 is difficult, and running position accuracy may be reduced.

Accordingly, as shown in FIG. 6C, an interleaf slitter 21 is disposed at a downstream side of an interleaf paper coil 19, the interleaf paper 18 is cleaved before being applied to the web 12, and a slit 18A is formed at a region which will correspond with edge portions of the PS plates 30. Thus, in the state in which the interleaf paper 18 is applied to the upper face of the web 12, the coating layer 77 is exposed (see (i) and (iv) in FIG. 7C).

After the interleaf paper 18 has been applied to the upper face of the web 12, the web 12 is cleaved by the cleaving section 10. However, a cleaving section 13 may be provided with functions of coating removal, microforming and cleaving. At the cleaving section 13, coating removal, microform machining and cleaving are performed by the cleaving section 13 to fabricate the PS plates 30 (see (v) and (vi) in FIG. 7C). In this manner, it is possible to achieve an increase in accuracy of processing positions.

Further again, it is possible to clear the coating layer 77 at the edge portions of the PS plates 30 by coating removal after slicing the web 12 (i.e., after fabricating the PS plates 30). That is, it is possible to perform coating removal on either of the web 12 and the PS plates 30. With regard to timing of the clearing by coating removal of the coating layer 77 from the edge portions, the coating removal can be performed at any time from coating of the surface of the web 12 until packing of the PS plates 30 as final products.

Herein, a width of the coating removal portions 96 is narrowed to a minimum possible within a range which does not affect product quality in association with slicing or cross-cutting. A width of the coating removal portions 96 which are kept at the final products is, specifically, less than 10 mm, in certain cases less than 5 mm, and in more particular cases less than 2 mm.

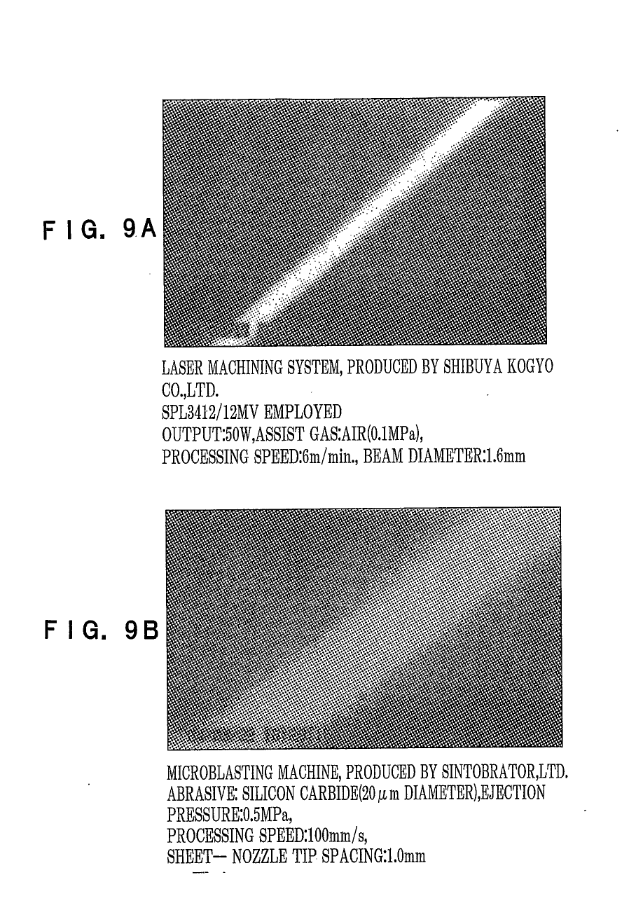

FIGS. 9A and 9B show, respectively, a case in which the coating removal portion 96 is formed by a CO₂ laser and a case in which the coating removal portion 96 is formed by microblasting. The CO₂ laser may be used in order to constrain width of the coating removal portion 96. As a process for performing coating removal, physical processes (laser ablation, a blasting treatment, etc.), chemical processes (dissolution, dissolving with an alkali and the like), and the like can be considered, and the process is not particularly limited.

Now, in cases in which CTP (computer to plate) plates are employed to output printing plates directly from printing data without using an intermediate material such as film or the like, there are the following problems.

When, for example, a photopolymer CTP plate is used, crack fogging and pressure fogging arise at the cleaving section 10 (see FIG. 2). In particular, in a case with a clearance system (see FIGS. 5C and 5D), because a roll-off is formed, cracks are formed in an oxidation layer covering the surface of the photopolymer CTP plate, electrons are provided through the cracks, polymerization of the photosensitive layer occurs, and a residue film is formed (“crack fogging”).

Accordingly, for photopolymer CTP plates, cleaving may be performed by a Goebel system (see FIGS. 5A and 5B). However, with a Goebel system, it is not possible to form roll-offs. Therefore, in comparison with a clearance slitting system, edge soiling characteristics of a newspaper product are poorer.

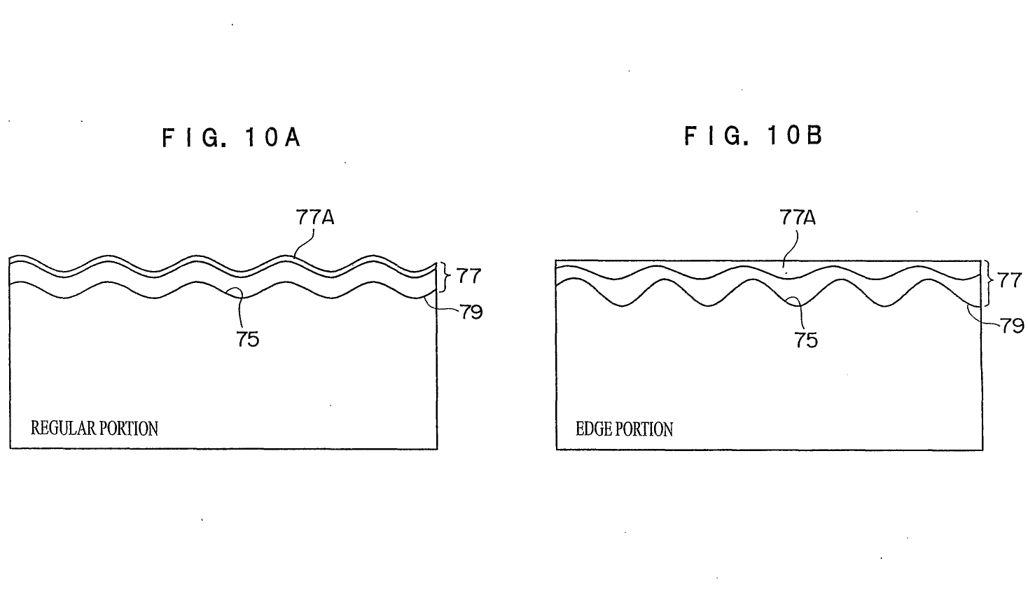

A case of a thermal CTP plate is shown in FIGS. 10A and 10B (FIG. 10A shows a regular portion (i.e., a region other than an edge portion) and FIG. 10B shows an edge portion). Because of electrolytic concentration, the grain 75 is deeper at the edge portion than at the regular portion, a layer thickness of a low-sensitivity photosensitive layer 77A varies, and a problem arises in that a residue film is formed at thickly coated portions.

In regard to such problems, Table 1 shows respective commercial printing specifications (for commercial printing applications) and newspaper printing specifications (for newspaper applications) in order to compare various slitting modes of the PS plates 30 and, in combination with the slitting modes, photopolymer CTP plates, thermal CTP plates and conventional-type printing plates (with current technologies, a zero level of cutting waste is achieved with conventional-type printing plates). These are discussed herebelow

TABLE 1

| Slitting Mode | | 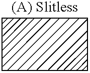 | 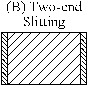 | 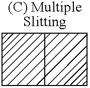 | 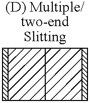 | 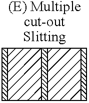 |
|---|---|---|---|---|---|---|
| Losses | | None | Cut-off losses | None | Cut-off losses | Cut-off and |
| | | | | | | cut-out losses |
| Roll-offs formed? | | No | Yes | No | No | Yes |
| (Clearance | | | | | | |
| slitting) | | | | | | |
| Commercial | Conventional | Good | Good | Good | Good | Good |
| use | plate | | | | | |
| | Photo- | Poor: Edge | Good | Poor: Pressure | Poor: Pressure | Good |
| | polymer | residue film | | marking/ | marking | |
| | CTP | | | Edge residue film | | |
| | Thermal | Poor: Edge | Good | Poor: Edge | Good | Good |
| | CTP | residue film | | residue film | | |
| Newspaper | Conventional | Poor: Edge | Good: | Poor: Edge soiling | Poor: Edge | Good: |
| use | plate | soiling | Clearance slitting | | soiling | Clearance slitting |
| | | | system | | | system |
| | Photo- | Poor: Edge | Fair: | Poor: Pressure | Poor: Pressure | Fair: |
| | polymer | residue film/ | Goebel slitting | marking/Edge | marking/Edge | Goebel slitting |
| | CTP | Edge soiling | system | residue film/Edge | residue | system |
| | | | | soiling | film/Edge soiling | |
| | Thermal | Poor: Edge | Good: | Poor: Edge | Poor: Edge | Good: |
| | CTP | residue film/ | Clearance slitting | residue film/Edge | soiling | Clearance slitting |
| | | Edge soiling | system | soiling | | system |

As shown in Table 1, slitting modes include a slitless type (“standard type”), a two-end slitting type, a multiple slitting type, a multiple/two-end slitting type, and a multiple cut-out slitting type. Here, halving types are described for multiple slitting, but obviously slitting modes which slit into three or more are also possible.

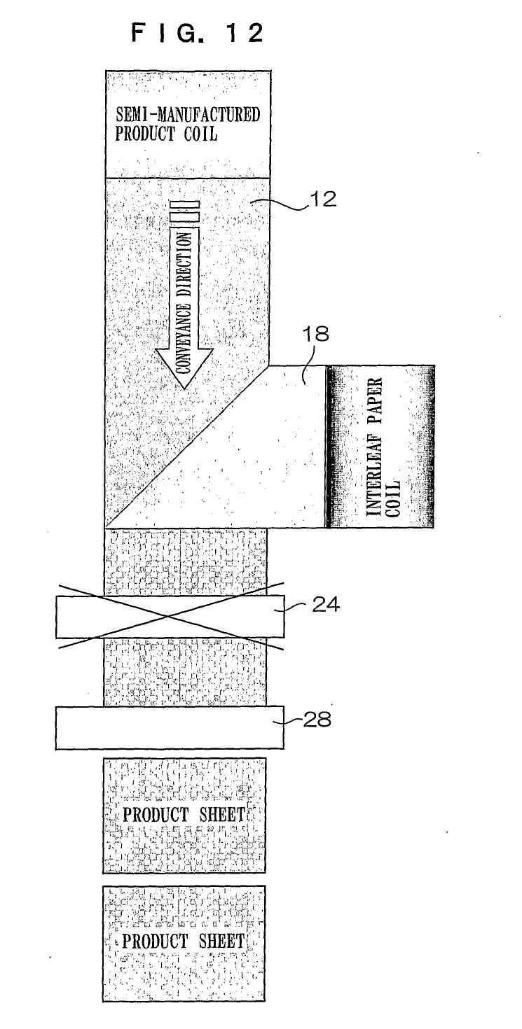

Here, in the slitless type case, as shown in FIG. 12, after the interleaf paper 18 has been applied to the web 12, the web 12 is sliced by the running cutter 28 in accordance with a predetermined length along the conveyance direction, and the cleaving roller 24 is not employed. Therefore, there is no cutting waste.

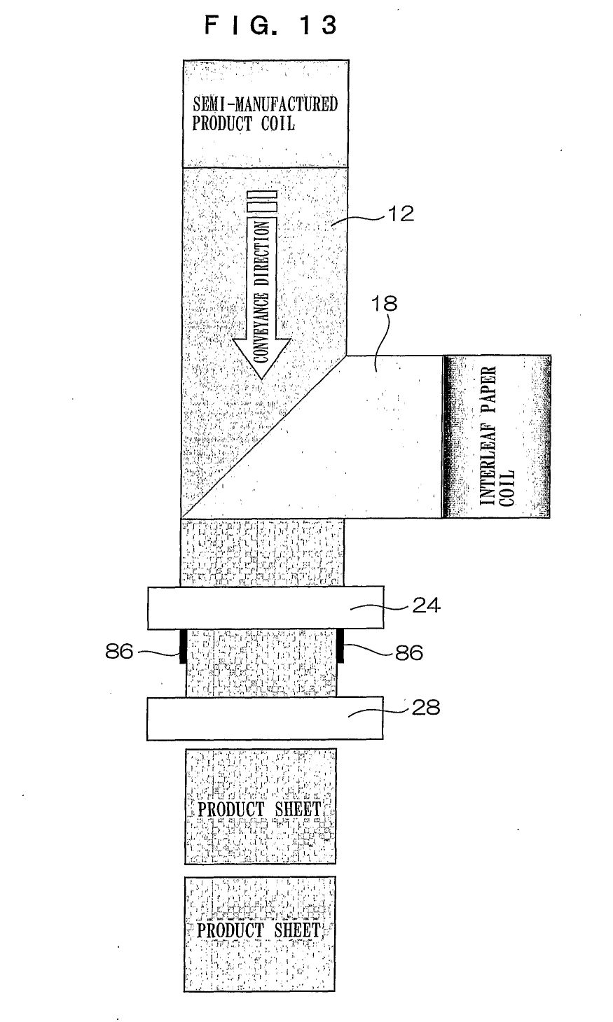

In the two-end slitting type, as shown in FIG. 13, after the interleaf paper 18 has been applied to the web 12, the two end portions in the width direction of the web 12 that is being conveyed are cleaved by the cleaving roller 24, and the web 12 is sliced by the running cutter 28 in accordance with a predetermined length along the conveyance direction. In this case, the cutting waste 86 is generated at the two end portions of the web 12.

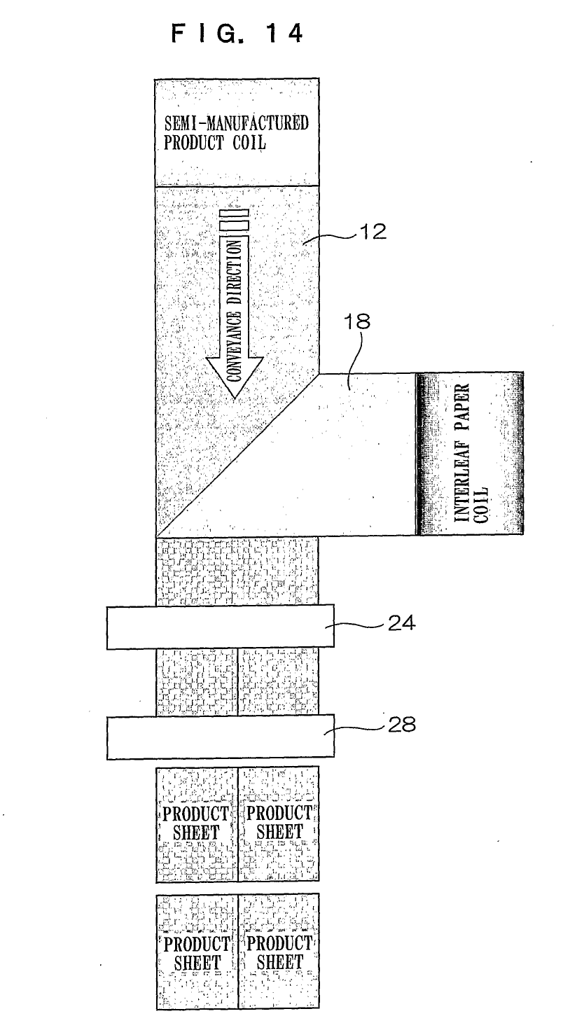

In the multiple slitting type, as shown in FIG. 14, after the interleaf paper 18 has been applied to the web 12, a width direction central portion of the web 12 that is being conveyed is cleaved by the cleaving roller 24, and the web 12 is sliced by the running cutter 28 in accordance with a predetermined length along the conveyance direction. In this case, the cutting waste 86 is not generated.

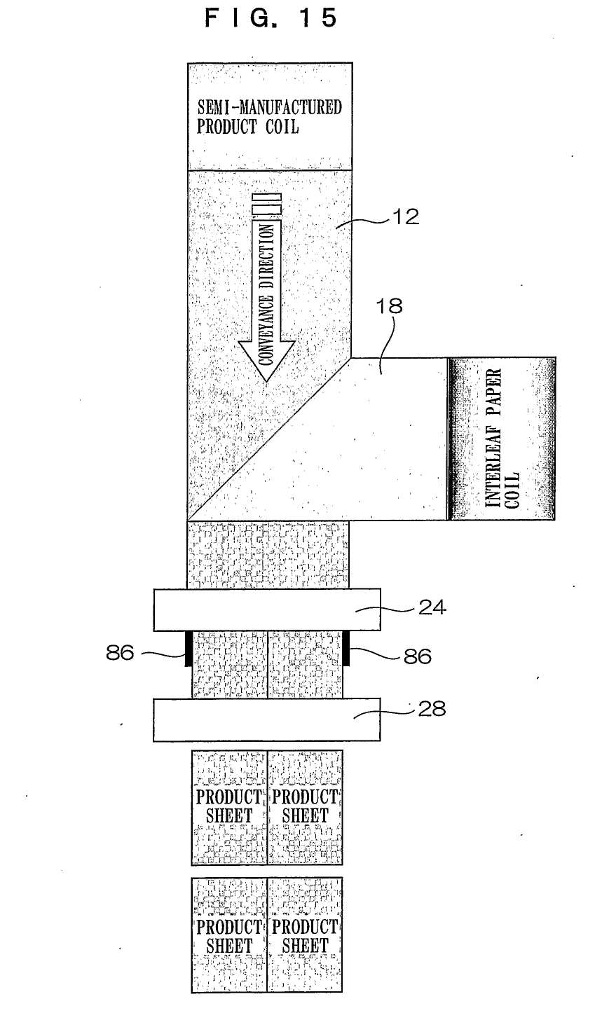

In the multiple/two-end slitting type, as shown in FIG. 15, after the interleaf paper 18 has been applied to the web 12, a width direction central portion and two end portions of the web 12 that is being conveyed are cleaved by the cleaving roller 24, and the web 12 is sliced by the running cutter 28 in accordance with a predetermined length along the conveyance direction. In this case, the cutting waste 86 is generated at the two end portions of the web 12.

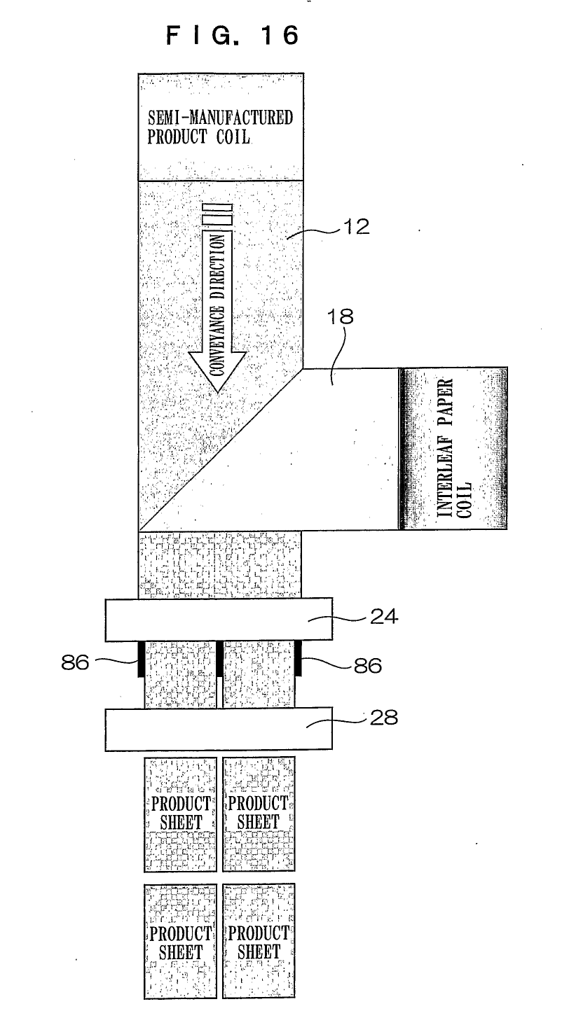

In the multiple cut-out slitting type, as shown in FIG. 16, after the interleaf paper 18 has been applied to the web 12, a width direction central portion and two end portions of the web 12 that is being conveyed are cleaved by the cleaving roller 24, and the web 12 is sliced by the running cutter 28 in accordance with a predetermined length along the conveyance direction. In this case, the cutting waste 86 is generated at the central portion and the two end portions of the web 12.

Now, because the cutting waste 86 is respectively generated in the two-end slitting type and the multiple cut-out slitting type, roll-off formation is possible therein. That is, in these types it is possible to cleave with a clearance slitting system.

However, while cutting off regions at which edge residue films would occur is necessary in regard to enabling product quality, the cutting waste 86 is a “product loss”. Hence, this is correspondingly reflected in costs, and costs of the PS plates 30 rise.

Therefore, it is desirable for there to be as little of the cutting waste 86 as possible. Yield (production efficiency with respect to coating width) is higher with the slitless type than with the two-end slitting type, which can facilitate a reduction in costs. Further, with respect to the two-end cut-out slitting type, the multiple/two-end slitting type and (even more so) the multiple slitting type give higher yields and can facilitate reductions in costs.

Cases of commercial printing specifications will be described first. With conventional plates, in every slitting mode, problems of pressure fogging and the like at end portions of the PS plates 30 do not occur. With photopolymer CTP plates, problems of edge residue films, pressure fogging and the like occur in the slitless type, the multiple slitting type and the multiple/two-end slitting type. With thermal CTP plates, edge residue films are apparent in the slitless type and the multiple slitting type.

In newspaper printing specifications, with conventional plates, photopolymer CTP plates and thermal CTP plates, problems of edge soiling, edge residue films and the like occur in the slitless type, the multiple slitting type and the multiple/two-end slitting type.

In cases of the two-end slitting type and the multiple cut-out slitting type, when a clearance slitting system is employed for cleaving of conventional plates or thermal CTP plates, problems with edge soiling and the like are eliminated. However, because a Goebel system is employed for cleaving in cases of photopolymer CTP plates, the roll-off portions 98 are not formed at the end portions of the web 12 as with the clearance slitting system, and edge-soiling characteristics in newspaper applications are slightly worse than with conventional plates and thermal CTP plates.

In consideration of the facts described above, tests were performed as follows.

Test 1

For photopolymer CTP plates, the multiple (halving)/two-end slitting type was employed to perform tests with the photopolymer CTP plates, with a view to suppressing pressure fogging due to coating removal (coating removal processing). Using: (1) product sheets produced by a conventional fabrication process; (2) product sheets which were slitted after coating removal processing of a central portion; (3) product sheets which were slitted after partial coating removal processing of a central portion; and (4) product sheets which were processed for coating removal of a central portion after slitting, Goebel slitting systems were employed at each of an L side (left side), C sides (the central portion) and an R side (right side).

TABLE 2

| | | L side | | R side | |
|---|---|---|---|---|---|
| Test Conditions | | product sheets | | product sheets | |
| No. | Coating removal processing | L side | C side | C side | R side |
| (1) | No coating removal | Good | Good | Poor | Good |
| | processing | | | | |
| (2) | Coating removal processing | Good | Good | Good | Good |
| | of central portion, then | | | | |
| | slitting | | | | |
| (3) | Partial coating removal | Good | Good | Good | Good |
| | processing of central | | | | |
| | portion, then slitting | | | | |
| (4) | Slitting, then coating | Good | Good | Good | Good |
| | removal processing of | | | | |
| | central portion | | | | |

he results were that, for (1), at a region corresponding with an upper blade at the time of slitting (the C side of the R side product sheet), a residue film was generated after development due to pressure fogging. However, for (2) to (4), because the coating removal processing was performed, residue films were not generated after development. From these results, it is seen that it is possible to eliminate cut-out losses during multiple slitting, subject to performing coating removal processing before or after slitting of a web.

Here, partial coating removal processing means partially removing the surface in a depth direction of the coating layer, which brings about a state in which only a surface portion of the coating layer is removed while the coating layer in a vicinity of a boundary between the support body and the coating layer is retained.

For example, in a case of photopolymer CTP plates, an over-coating layer and a portion of a photosensitive layer are removed, producing a state in which a portion of the photosensitive layer remains on the support. Hence, a residue film is unlikely to be generated due to pressure or cracking. Therefore, it is not necessary for the coating layer at a region at which fogging would occur to be completely cleared by coating removal.

A thermal CTP plate has a multiple-layer design in which a lower layer is a high-sensitivity layer and an upper layer is a low-sensitivity layer. A thick film portion of the upper layer is present at edge portions, which leads to development failures.

In order to avoid the occurrence of such development failures, the upper layer and lower layer may be wholly removed. However, if only a region at which the upper layer is thicker is removed, such that thickness is no more than a thickness equivalent to other layers, residue films will no longer occur. Therefore, by removing a region at which the upper layer is thick, which is the cause of occurrences of development failures (residue films), problems relating to development failures are eliminated.

If the coating layer is completely removed, aluminium will melt if the web is excessively illuminated by a laser. Consequently, an energy range will be restricted and control will be more difficult. However, with partial coating removal, an allowable range of illumination energy is broader. Therefore, control is easier. That is, partial coating removal has the advantage that control of conditions of coating removal by laser can be less precise.

Test 2

Next, for photopolymer CTP plates in newspaper applications, with a view to suppressing crack fogging due to coating removal and improving edge quality, with the multiple (halving)/two-end slitting type, clearance slitting systems were employed at each of an L side (left side), C sides (the central portion) and an R side (right side). Thus, roll-off shapes were formed at edge portions of the web at the time of cleaving.

TABLE 3

| | | L side | | R side | |
|---|---|---|---|---|---|
| Test Conditions | | product sheets | | product sheets | |
| No. | Coating removal processing | L side | C side | C side | R side |
| (1) | No coating removal | Poor | Poor | Poor | Poor |
| | processing | | | | |
| (2) | Coating removal | Good | Good | Good | Good |
| | processing, then | | | | |
| | clearance slitting | | | | |
| (3) | Partial coating removal | Good | Good | Good | Good |
| | processing, then clearance | | | | |
| | slitting | | | | |
| (4) | Clearance slitting, then | Good | Good | Good | Good |
| | coating removal processing | | | | |

The results were that, for (1), at edge vicinities of the web at the time of slitting, cracks were formed in an oxidation film at the surface of the web, and residue films were formed at those portions after development. For (2) to (4), residue films were not formed after development. From these results, it is seen that, although it is not conventionally possible to form roll-off shapes with photopolymer CTP plates, it is possible to form roll-off shapes without causing residue films to occur, subject to incorporating the coating removal processing before or after clearance slitting. That is, edge soiling characteristics are improved, and an edge quality equivalent to conventional-type PS plates for newspaper applications can be realized.

Test 3

On the basis of the results of the above-described tests 1 and 2, it was further investigated whether it was possible to eliminate cut-out losses in multiple slitting by combining coating removal processing, a chamfering process and Goebel slitting for each of newspaper-use conventional PS plates, thermal CTP plates and photopolymer CTP plates.

TABLE 4

| | | | | Evaluation | |
|---|---|---|---|---|---|
| Test conditions | | | | Results | |
| | | Second | Third | Edge | Cut-out |
| No. | First process | process | process | soiling | losses |
| Comparative | Clearance | — | — | Good | Loss |
| example | slitting | | | | |
| Condition (1) | Goebel | Coating | Chamfering | Good | No loss |
| | slitting | removal | | | |
| Condition (2) | | Cham- | Coating | Good | No loss |
| | | fering | removal | | |
| Condition (3) | Coating | Goebel | Chamfering | Good | No loss |
| | removal | slitting | | | |
| Condition (4) | | Cham- | Goebel | Good | No loss |
| | | fering | slitting | | |
| Condition (5) | Chamfering | Goebel | Coating | Good | No loss |
| | | slitting | removal | | |
| Condition (6) | | Coating | Goebel | Good | No loss |
| | | removal | slitting | | |

For the comparative example, in the process of fabrication of product sheets, cleaving is performed by a clearance slitting system. For conditions (1) and (2), cleaving is performed by a Goebel slitting system. Then, after the cleaving, in condition (1), coating removal processing is applied to the cleaved portions, and the coating removal-processed portions are chamfered. In condition 2, the chamfering process is applied to the cleaved portions, and the chamfered portions are subjected to coating removal processing.

In conditions (3) and (4), before cleaving is performed, the respective web edge portions are subjected to coating removal processing. Then, in condition (3), the coating removal-processed portions are cleaved by the Goebel slitting system, and the chamfering process is applied to the cleaved portions. In condition (4), the coating removal-processed portions are chamfered, and than the chamfered portions are cleaved by the Goebel slitting system.

In conditions (5) and (6), first, the respective web edge portions are chamfered. Then, after the chamfering, in condition (5), the chamfered portions are cleaved by the Goebel slitting system, and the cleaved portions are subjected to coating removal processing. In condition (6), the chamfered portions are subjected to coating removal processing, and then the coating removal-processed portions are cleaved by the Goebel slitting system.

The results were that, in the comparative example, because clearance slitting was employed, edge soiling did not occur but cut-out losses were generated, while in conditions (1) to (6), even though Goebel slitting systems were employed, edge soiling did not occur.

That is, from these test results, it is seen that cut-out losses can be eliminated by combining the coating removal processing of the present invention with a chamfering process. When shape control is performed before or after cleaving, it is possible to obtain a particular chamfered shape regardless of the system of cleaving. Therefore, it is not necessary to combine a pair of blades at a central portion as shown in FIG. 4, and cut-out losses can be eliminated. Furthermore, because crack fogging is eliminated by the coating removal, it is possible to improve quality with regard to edge soiling even though the coating removal is combined with clearance slitting.

Further yet because the edge portions of the PS plates 30 are formed to roll-off shapes by the chamfering process, it is not necessary to form roll-offs by plastic deformation at the time of cleaving. That is, it is not necessary to employ a clearance system at the cleaving section 10, and a Goebel system can be applied. With a Goebel system (see FIG. 5A), because no clearance is provided between the upper blade 50 and the lower blade 56, it is possible to raise precision of the cleaving position.

Test 4

Next, for newspaper-use conventional PS plates, thermal CTP plates and photopolymer CTP plates, coating removal processing and the chamfering process were combined, and it was investigated whether it is possible to eliminate the cutting waste associated with clearance slitting of cut-off portions.

TABLE 5

| | | | Thermal/ | | Photopolymer | |
|---|---|---|---|---|---|---|
| | | | Conventional | | CTP | |
| | First | Second | Edge | Cut-off | Edge | Cut-off |
| No. | process | process | soiling | losses | soiling | losses |
| Comparative | Clearance | — | Good | Loss | Poor | Loss |
| example | slitting | | | | | |
| Condition | Coating | Cham- | Good | No loss | Good | No loss |
| (1) | removal | fering | | | | |
| Condition | Cham- | Coating | Good | No loss | Good | No loss |
| (2) | fering | removal | | | | |

For the comparative example, in the process of fabrication of product sheets, cleaving is performed by a clearance slitting system. For conditions (1) and (2), cleaving is not performed. In condition (1), end portions of the web are subjected to coating removal processing, and the coating removal-processed portions are chamfered. In condition (2), end portions of the web are subjected to the chamfering process, and the chamfered portions are subjected to coating removal processing.

With photopolymer CTP plates in the comparative example, because crack fogging occurs, a clearance slitting system cannot be employed, and roll-off shapes cannot be formed. With conventional PS plates and thermal CTP plates, soiling does not occur at the edges, but cutting waste is inevitably generated in this comparative example.

Where the present invention is employed in the current test, the coating removal processing of the present invention is combined with cutaway shape-machining. Thus, it is seen that cutting waste of cut-off portions is not generated for newspaper applications, and edge quality can be raised.

Test 5

At cut-off portions of thermal CTP plates and photopolymer CTP plates, multi-layer structures make occurrences of coating defects more likely After development, such coating defects may form residue films. Consequently, in a conventional production process, cut-off portions have to be discarded. Accordingly, it was next investigated whether it is possible to eliminate cutting waste by applying the coating removal processing to the cut-off portions of a multi-layer mode.

TABLE 6

| | Coating removal | Photopolymer | |
|---|---|---|---|
| No. | processing | CTP | Thermal CTP |
| Comparative | No | Poor | Poor |
| example | | | |
| Condition (1) | Yes | Good | Good |
| Condition (2) | Partial coating | Good | Good |
| | removal | | |

A case in which the coating removal processing was not performed is shown for the comparative example, the coating removal processing was performed in condition (I), and partial coating removal was performed in condition (2). The results were that coating defects occurred for both thermal CTP and photopolymer CTP in the case in which the coating removal processing was not performed, while coating defects did not occur in conditions (1) and (2).

That is, by applying the coating removal processing of the present invention, it is possible to set cutting waste, which cannot be provided as the finished product, to zero. Even for CTP, with three-layer structures, it is possible to realize fill-width finished products, and both an increase in production efficiency and a substantial reduction in costs can be expected.

Note that the above-described PS plates, whose edge portions are subjected to coating removal, and fabrication processes thereof are not particularly limiting. The present invention can be applied to any PS plates, such as conventional-type printing plates (negative or positive), photopolymer-type direct printing plates, thermal-type direct printing plates, electrophotography-type direct printing plates, processless printing plates and so forth.

A photosensitive planographic printing plate of the present invention may be provided with, at a coating removal portion, grain and an oxidation layer on a surface of the grain, for providing hydrophilicity subsequent to exposure and development.

At a non-image portion of the photosensitive planographic printing plate in a state after exposure and development and platemaking, functions for preventing ink adherence and absorbing condensation are necessary. With an ordinary photosensitive planographic printing plate, hydrophilic functionality is provided by surface processes such as etching, graining and oxidation. Accordingly, in the structure described above, at the coating removal portion, the grain and an oxidation film at the surface of the grain are retained. Thus, hydrophilicity can be maintained.

In the present invention, a chamfered portion (which may be a plastic deformation formed by pressure force at a time of cutting (i.e., a “roll-off”)) may be formed at a corner portion of the coating removal portion.

In order to prevent edge soiling, as well as providing hydrophilicity, it is important to form a shape such that edge regions of the photosensitive planographic printing plate are unlikely to come into contact with a blanket roller in a printer. Accordingly, in the structure described above, chamfered portions are formed at the corner portions of coating removal portions. Thus, pressure on a blanket roller from the edge portions of the photosensitive planographic printing plate is lowered, transference of ink round onto the blanket roller from side end faces of the photosensitive planographic printing plate is prevented, and edge soiling of the photosensitive planographic printing plate is prevented.

In the present invention, desensitization processing may be applied to a side end face of the photosensitive planographic printing plate.

In such a case, because the desensitization processing has been applied to the side end faces of the photosensitive planographic printing plate, transference of ink round onto the blanket roller from side end faces of the photosensitive planographic printing plate is prevented, and edge soiling prevention effects can be enhanced.

Because hydrophilicity is raised and ink is less likely to adhere at the edge portions of the photosensitive planographic printing plate, edge soiling can be suppressed. Even if ink does adhere to the edge portions, the adhered ink will be unlikely to transfer to the blanket roller, and a reduction in edge soiling can be implemented.

That is, effective means for preventing edge soiling can be implemented by applying the desensitization processing to the side end faces of the photosensitive planographic printing plate to make the side end faces resistant to the adherence of ink. Obviously, in addition to side face portions of the photosensitive planographic printing plate, the application of the desensitization processing may extend from the side face portions to the coating removal portions.

A process of the present invention may further include forming a chamfered portion at a corner portion of the coating removal portion wherein, thereafter, the slicing or cross-cutting keeps the chamfered portion.

In such a case, after the chamfered portion has been formed at the corner portion of the edge portion of the coating removal portion, slicing or cross-cutting is performed to retain the chamfered portion. Thus, it is possible to form particular roll-off shapes at which the coating layer is not present at the edge portions of the photosensitive planographic printing plate which has been sliced or cross-cut.

A process of the present invention may further include preparatorily forming a chamfered portion at a corner portion of the edge portion of the at least one edge of the sheet-form photosensitive planographic printing plate wherein, thereafter, the clearing by coating removal is performed and the slicing or cross-cutting keeps the chamfered portion.

In this case, because the coating removal processing is applied after the chamfered portion has been previously formed at the corner portion of the edge portion of the photosensitive planographic printing plate and the slicing or cross-cutting is performed to retain the chamfered portion, effects substantially the same as the effects previously described are obtained.

The process of the present invention may further include, after clearing the edge portion of the at least one edge of the sheet-form photosensitive planographic printing plate by coating removal, forming a chamfered portion at a corner portion of the coating removal portion.

In this case, because the chamfered portion is formed at the corner portion of the edge portion of the photosensitive planographic printing plate after the coating removal processing has been applied, the chamfered portion is not plastically deformed by the slicing or cross-cutting.

The photosensitive planographic printing plate fabrication process of the present invention may further include, before the clearing the edge portion of the at least one edge of the sheet-form photosensitive planographic printing plate by coating removal, preparatorily forming a chamfered portion at a corner portion of the edge portion.

In this case, because the chamfered portion is formed at the corner portion of the edge portion of the photosensitive planographic printing plate before the edge portion is cleared by coating removal, effects substantially the same as the effects previously described are obtained.

The photosensitive planographic printing plate fabrication process of the present invention may further include, after the clearing by coating removal and slicing or cross-cutting have been performed, applying desensitization processing to the coating removal portion.

In this process, because the desensitization processing is applied to the coating removal portion after the coating removal and cutting or slicing have been performed, it is possible to further ameliorate edge soiling of the photosensitive planographic printing plate.

With the present invention being structured as described above, in the first aspect, the coating layer is removed from an edge region of the photosensitive planographic printing plate, that is, a portion of slicing or cross-cutting of the photosensitive planographic printing plate, and pressure fogging due to pressure during slicing or cross-cutting will not occur. Further, fogging which is caused by a polymerization reaction occurring, due to cracks being formed at the slicing or cross-cutting portion of the photosensitive planographic printing plate, the surface of the support being exposed and electrons being supplied to the surface, will not occur. Consequently, cutting waste at the time of cutting can be reduced, and yield (production efficiency with respect to coating width) can be improved.

Further, at the coating removal portion, hydrophilicity can be maintained by the grain and the oxidation film on or the surface of the grain being retained.

Further again, when the chamfered portion is formed at the corner portion of the coating removal portions, pressure on a blanket roller from the edge portion of the photosensitive planographic printing plate is lowered, transference of ink from the side end face of the photosensitive planographic printing plate round onto the blanket roller is prevented, and edge soiling of the photosensitive planographic printing plate is prevented.

Further still, when the desensitization process is applied to the side end face of the photosensitive planographic printing plate, transference of ink from the side end face of the photosensitive planographic printing plate round onto the blanket roller is prevented, and the edge soiling prevention effect is enhanced.

In the process of the second aspect of the present invention, because the coating layer is preparatorily cleared by coating removal before the slicing or cross-cutting, pressure fogging will not occur at the edge portion of the photosensitive planographic printing plate.

Further, when the whole or a surface portion of the coating layer is cleared by coating removal after the slicing or cross-cutting, fogging will not occur due to cracks being formed at a region of slicing or cross-cutting of the photosensitive planographic printing plate.

Further again, when the slicing or cross-cutting keeps the chamfered portion after the chamfered portion has been formed at the corner portion of the edge portion of the coating removal portion, a desired roll-off shape at which the coating layer is not present can be formed at the edge portion of the photosensitive planographic printing plate that has been sliced or cross-cut.

Further still, when the chamfered portion is formed at the corner portion of the coating removal portion after the edge portion of the photosensitive planographic printing plate has been cleared by coating removal, the chamfered portion will not be plastically deformed by the slicing or cross-cutting.

Further yet, when the desensitization process is applied to the coating removal portion after the coating removal and the cutting or slicing have been performed, it is possible to further ameliorate edge soiling of the photosensitive planographic printing plate.

The embodiment described above is an example, and various modifications can be applied within a scope not departing from the spirit of the present invention.

1. A photosensitive planographic printing plate at which a coating layer is formed on a support body, which coating layer is to be exposed and developed,
wherein a coating removal portion is formed at at least one edge of the photosensitive planographic printing plate, at which coating removal portion the coating layer has been cleared by coating removal.

2. The photosensitive planographic printing plate of claim 1, comprising, at the coating removal portion, grain and an oxidation layer on a surface of the grain, for providing hydrophilicity subsequent to exposure and development.

3. The photosensitive planographic printing plate of claim 1, wherein a chamfered portion is formed at a corner portion of the coating removal portion.

4. The photosensitive planographic printing plate of claim 1, wherein desensitization processing has been applied to a side end face of the photosensitive planographic printing plate.

5. A process for fabrication of a photosensitive planographic printing plate which is formed as a sheet by slicing or cross-cutting, the process comprising:
forming a coating layer on a continuously running web, the coating layer being structured with at least one functional coating film;
at an edge portion of at least one edge of the sheet-form photosensitive planographic printing plate, clearing the whole or a surface portion of the coating layer by coating removal, and
after the clearing by coating removal, slicing or cross-cutting a coating removal portion, which has been cleared by the coating removal, at the edge portion.

6. A process for fabrication of a photosensitive planographic printing plate which is formed as a sheet by slicing or cross-cutting, the process comprising:
forming a coating layer on a continuously running web, the coating layer being structured with at least one functional coating film;
slicing or cross-cutting at an edge portion of at least one edge of the sheet-form photosensitive planographic printing plate; and
after the slicing or cross-cutting, clearing the whole or a surface portion of the coating layer at the edge portion by coating removal.

7. The photosensitive planographic printing plate fabrication process of claim 5, further comprising forming a chamfered portion at a corner portion of the coating removal portion
wherein, thereafter, the slicing or cross-cutting keeps the chamfered portion.

8. The photosensitive planographic printing plate fabrication process of claim 5, further comprising preparatorily forming a chamfered portion at a corner portion of the edge portion of the at least one edge of the sheet-form photosensitive planographic printing plate wherein, thereafter, the clearing by coating removal is performed and the slicing or cross-cutting keeps the chamfered portion.

9. The photosensitive planographic printing plate fabrication process of claim 6, further comprising, after the clearing the edge portion of the at least one edge of the sheet-form photosensitive planographic printing plate by coating removal, forming a chamfered portion at a corner portion of the coating removal portion.

10. The photosensitive planographic printing plate fabrication process of claim 6, further comprising, before the clearing the edge portion of the at least one edge of the sheet-form photosensitive planographic printing plate by coating removal, preparatorily forming a chamfered portion at a corner portion of the edge portion.

11. The photosensitive planographic printing plate fabrication process of claim 5, further comprising, after the clearing by coating removal and slicing or cross-cutting have been performed, applying desensitization processing to the coating removal portion.
